(19) United States
(12) Patent Application Publication
(10) Pub. No.: US 2025/0273582 A1
(43) Pub. Date: Aug. 28, 2025

(54) INTERCONNECTIONS TO PACKAGE SUBSTRATES FOR INTERCONNECT BRIDGES

(71) Applicant: Intel Corporation, Santa Clara, CA (US)

(72) Inventors: Jeremy D. ECTON, Gilbert, AZ (US); Naiya SOETAN-DODD, Mesa, AZ (US); Brandon C. MARIN, Gilbert, AZ (US); Shuren QU, Gilbert, AZ (US); Mohamed R. SABER, College Station, TX (US); Bohan SHAN, Chandler, AZ (US); Tarek A. IBRAHIM, Mesa, AZ (US); Srinivas PIETAMBARAM, Chandler, AZ (US); Gang DUAN, Chandler, AZ (US); Ravindranath MAHAJAN, Chandler, AZ (US); Suddhasattwa NAD, Chandler, AZ (US); Benjamin DUONG, Phoenix, AZ (US); Shruti SHARMA, Chandler, AZ (US); Mollie STEWART, Lake Oswego, OR (US)

(21) Appl. No.: 18/587,520

(22) Filed: Feb. 26, 2024

(51) Int. Cl. H01L 23/538; H01L 23/00

(52) U.S. Cl. CPC H01L 23/5386; H01L 23/5383; H01L 23/5384; H01L 24/14; H01L 24/16; H01L 24/32; H01L 24/73; H01L 2224/14177; H01L 2224/16227; H01L 2224/32225; H01L 2224/73204

(57) ABSTRACT

Semiconductor package substrates and assemblies comprising semiconductor package substrates are provided. The semiconductor package substrates can include interconnect bridges having through-bridge vias. The semiconductor package substrates can also include collapsible cavities in dielectric layers. The interconnect bridges can include protruding conductive pads that form electrical connections with the semiconductor package substrate. Assemblies include semiconductor package substrates and semiconductor devices.

### FIELD

Descriptions are generally related to semiconductor manufacture, and more particular descriptions are related to package substrates for semiconductor devices and package substrates that include interconnect bridges.

### BACKGROUND

Semiconductor chips are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

Form factor miniaturization and increased levels of integration for high performance semiconductor devices are driving the need for sophisticated packaging approaches in the semiconductor industry. Die partitioning enables small form factors and high performance. Die partitioning can also improve semiconductor chip manufacturing yields but it can require fine pitched die-to-die interconnections. Interconnect bridges that can be embedded in package substrates can enable a lower cost and simpler 2.5D packaging approach (that employs an interconnect bridge in the package substrate) for very high-density interconnects between heterogeneous dies on a single package. An interconnect bridge can be embedded in a semiconductor device package substrate, and can enable very high density die-to-die connections only where needed. Interconnect bridges can be, for example, Embedded Multi-die Interconnect Bridges (EMIBs). Standard flip chip assembly can be used for robust power delivery interconnections and to connect high-speed signals directly from chip to the package substrate.

### BRIEF DESCRIPTION OF THE DRAWINGS

The figures are provided to aid in understanding the invention. The figures can include diagrams and illustrations of exemplary structures, assemblies, data, methods, and systems. For ease of explanation and understanding, these structures, assemblies, data, methods, and systems, the figures are not an exhaustively detailed description. The figures therefore should not be understood to depict the entire metes and bounds of structures, assemblies, data, methods, and systems possible without departing from the scope of the invention. Additionally, features are not necessarily illustrated relatively to scale due in part to the small sizes of some features and the desire for clarity of explanation in the figures.

FIGS. 1A-1C show a semiconductor package substrate and assemblies that include the semiconductor package substrate.

FIGS. 2A-2B illustrate regions of a semiconductor package substrate.

FIGS. 3A-3C provide an additional semiconductor package substrate and assemblies that include the semiconductor package substrate.

FIGS. 4A-4C show an additional semiconductor package substrate and assemblies that include the semiconductor package substrate.

FIG. 5 illustrates an exemplary multi-chip package in which the package incorporates interconnect bridges.

FIGS. 6A-6F illustrate a method for manufacturing a semiconductor package substrate comprising an interconnect bridge.

FIGS. 7A-7G illustrate additional methods for manufacturing a semiconductor package substrate comprising an interconnect bridge.

FIG. 8 provides an additional method for manufacturing a semiconductor package substrate comprising an interconnect bridge.

FIG. 9 provides an exemplary computing system.

Descriptions of certain details and implementations follow, including non-limiting descriptions of the figures, which depict some examples and implementations.

### DETAILED DESCRIPTION

References to one or more examples are to be understood as describing a particular feature, structure, or characteristic included in at least one implementation of the invention. The phrases “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following some other event or events. Other sequences of operations can also be performed according to alternative embodiments. Furthermore, additional operations may be added or removed depending on the application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Flow diagrams as illustrated herein provide examples of sequences of various process actions. The flow diagrams can indicate operations to be executed by a software or firmware routine, as well as physical operations. Physical operations can be performed by semiconductor processing equipment. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described can include software, hardware, or a combination of these. Some components can be implemented as software modules, hardware modules, special-purpose hardware (for example, application specific hardware, application specific integrated circuits (ASICs), digital signal processors (DSPs), etc.), embedded controllers, or hardwired circuitry). Other components can be semiconductor processing equipment that is able to perform physical operations such as, for example, lithography, chemical or laser etching, material deposition (for example, chemical vapor deposition, atomic layer deposition, electrochemical deposition, and/or sputtering), chemical mechanical polishing, and/or pick-and-place operations.

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described. A machine-readable storage medium includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). Instructions can be stored on the machine-readable storage medium in a non-transitory form. A communication interface includes any mechanism that interfaces to, for example, a hardwired, wireless, or optical medium to communicate to another device, such as, for example, a memory bus interface, a processor bus interface, an Internet connection, a disk controller.

Terms such as chip, die, IC (integrated circuit) chip, IC die, microelectronic chip, microelectronic die, semiconductor die, semiconductor device, and/or semiconductor chip are interchangeable and refer to a semiconductor device comprising integrated circuits.

Semiconductor chip manufacturing processes are sometimes divided into front end of the line (FEOL) processes and back end of the line (BEOL) processes. Electronic circuits and active and passive devices within the chip, such as for example, transistors, capacitors, resistors, and/or memory cells, are manufactured in what can be referred to as FEOL processes. Memory cells include, for example, electronic circuits for random access memory (RAM), such as static RAM (sRAM), dynamic RAM (DRAM), read only memory (ROM), non-volatile memory, and/or flash memory. FEOL processes can be, for example, complementary metal-oxide semiconductor (CMOS) processes. BEOL processes include metallization of the chip where interconnects are formed in layers and the feature size of the interconnect increases in layers nearer the surface of the semiconductor chip. Interconnects in, for example, semiconductor chips that are integrated into heterogeneous packages (such as, for example, packages that include memory and logic chips), can also include through silicon vias (TSVs) that transverse the semiconductor chip device region. Semiconductor devices that have TSVs can blur distinctions between BEOL and FEOL processes.

Semiconductor chip interconnects can be created by forming a trench or though-layer via by etching a trench or via structure into a dielectric layer and filling the trench or via with metal. Dielectric layers can comprise, for example, low-K dielectrics, SiO₂, silicon nitride (SiN), silicon carbide (SiC), and/or silicon carbonitride (SiCN). Low-K dielectrics include for example, fluorine-doped SiO₂, carbon-doped SiO₂, porous SiO₂, porous carbon-doped SiO₂, combinations for the foregoing, and also these materials with gas-filled gaps. Dielectric layers that include conducting features can be intermetal dielectric (ILD) features.

The terms “package,” “packaging,” “IC package,” or “chip package,” “microelectronics package,” or “semiconductor chip package” are interchangeable and generally refer to an enclosed carrier of one or more dies, in which the dies are attached to a package substrate and encapsulated. The package substrate provides electrical interconnects between the die(s) and other dies and/or a motherboard or other printed circuit board for I/O (input/output) communication and power delivery. A package with multiple dies can, for example, be a system in a package.

A package substrate generally includes dielectric layers or structures having conductive structures on, through, and/or embedded in the dielectric layers. The dielectric layers can be, for example, build-up layers. Dielectric build-up materials include, polyimides and Ajinomoto build-up films (ABFs), although other dielectric materials are possible. Semiconductor package substrates can have cores or be coreless. Semiconductor packages having cores can have dielectric layers such as build-up layers on more than one side of a core, such as on two opposite sides of a core. Cores can include through-core vias that contain a conductive material. Other structures or devices are also possible within a package substrate.

A “core” or “package core” generally refers to a layer usually embedded within a package substrate. The core can provide structure or stiffness to a package substrate. A core is an optional feature of a package substrate. The core can be a dielectric organic or inorganic material and may have conductive vias extending through the layer. The conductive vias can include a metal, for example, copper. A package core can, for example, be comprised of a glass material (such as, for example, aluminosilicate, borosilicate, alumino-borosilicate, silica, and fused silica), silicon, silicon nitride, silicon carbide, gallium nitride, or aluminum oxide. In some examples, core materials are glass-fiber reinforced organic resins such as epoxy-based resins. A further example package substrate core is FR4 (woven glass fiber reinforces epoxy). In other examples, package substrate cores are solid amorphous glass materials.

In further examples of a package substrate core, the substrate core is a glass core comprising a solid amorphous glass material. The glass substrate core can comprise a glass such as, for example, aluminosilicate, borosilicate, alumino-borosilicate, silica, and fused silica, that additionally optionally comprises one or more of the following: Al₂O₃, B₂O₃, MgO, CaO, SrO, BaO, SnO₂, Na₂O, K₂O, SrO, P₂O₃, ZrO₂, Li₂O, Ti, and/or Zn. In further examples of glass cores, the glass can comprise silicon and oxygen, as well as optionally any one or more of: aluminum, boron, magnesium, calcium, barium, tin, sodium, potassium, strontium, phosphorus, zirconium, lithium, titanium, and/or zinc. In some examples, a glass package substrate core comprises at least 23% silicon, at least 26% oxygen by weight. In further examples, the glass package substrate core comprises at least 23% silicon, at least 26% oxygen, and at least 5% aluminum by weight.

Additionally, exemplary solid amorphous glass substrate cores can be considered to have a rectangular prism volume. The rectangular prism volume can contain vias that have been filled with one or more different materials. A material in a via can be a conducting metal such as, for example, copper. Exemplary solid amorphous glass substrate cores can have a thickness in the range of 50 μm to 1.4 mm. Additionally, the package substrate can include a multi-layer glass substrate. The package substrate in this example may be a coreless substrate. The multi-layer glass substrate can have a thickness, for example, in the range of 25 μm to 50 μm. Further, glass substrate cores can have dimensions on a side of 10 mm to 250 mm. For example, the substrate core can be 10 mm by 10 mm up to 250 mm by 250 mm in two dimensions, but substrate cores do not necessarily have to have the same value in both dimensions.

A package substrate can include one or more interconnect bridges. An interconnect bridge can be partially, fully, or not embedded into the package substrate. An interconnect bridge provides interconnects between chips that are housed on the package substrate. The interconnects can be for I/O between the chips. Some interconnect bridges, such as ones that have conducting through-bridge vias, can also provide power to an operably electrically connected chip. The interconnect bridge can include regions having traces that have a smaller width dimension (the smallest dimension of the trace), a smaller height dimension, and/or a length dimension than the vias and traces of the surrounding package substrate. For example, width dimensions (or smallest dimension) can be 3 μm or less and/or 10 μm or less in some regions. The interconnect bridges can also have smaller trace spacings than the surrounding package substrate. For example, trace center-to-center spacings can be 3 μm and/or less or 10 μm or less in some regions. The bridge can comprise, for example, a silicon substrate, a silicon-on-insulator substrate, one or more organic polymeric materials, a float glass substrate, a borosilicate glass substrate, a silicon dioxide substrate, and/or a silicon nitride substrate. The substrate can additionally comprise, for example, one or more dielectric layers that are comprise of, silicon oxides, silicon nitride, silicon oxynitride, carbon-doped oxide, methyl silsesquioxane, hydrogen silsesquioxane, die backside film (DBF), an epoxy film, a B-stage epoxy film, other dielectric material. The bridge can also be a coreless substrate comprised of a plurality of dielectric layers. The dielectric layers can additionally be, for example, die backside film (DBF), an epoxy film, a B-stage epoxy film, or another dielectric material. Other materials are possible.

For packages that include interconnect bridges, the pitch in the interconnect bridge region for first level interconnects (FLIs) assemblies can be less than the pitch for other regions of the FLI assembly. The pitch in the interconnect bridge region for FLIs can be, for example, less than or equal to 25 μm.

Incorporating through-bridge vias (TBVs) into interconnect bridges can enable power to be routed from a substrate package cavity to a semiconductor device attached to a package substrate. Through-bridge-vias can reduce the number of substrate routing layers required in a package substrate and can result in improved packaging yields. An interconnect bridge having TBVs can be for example, EMIB with TBVs, or EMIB-T. Depending on the bridge substrate material, a TBV may also be described as a through-silicon via (TSV) if the via traverses a region comprised of silicon, for example. However, assembling an interconnect bridge having TBVs into substrate package can present yield challenges and architectures which simplify the assembly process of interconnect bridges having TBVs into a package substrate cavity are important.

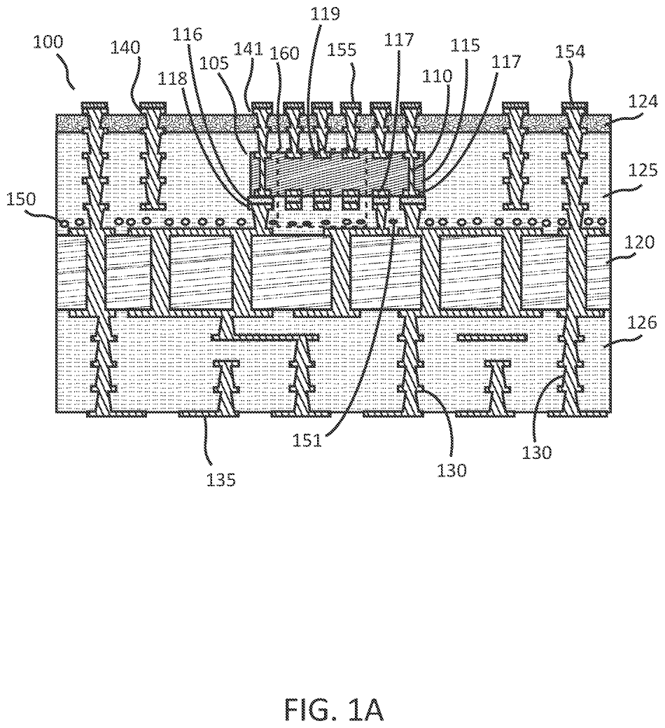

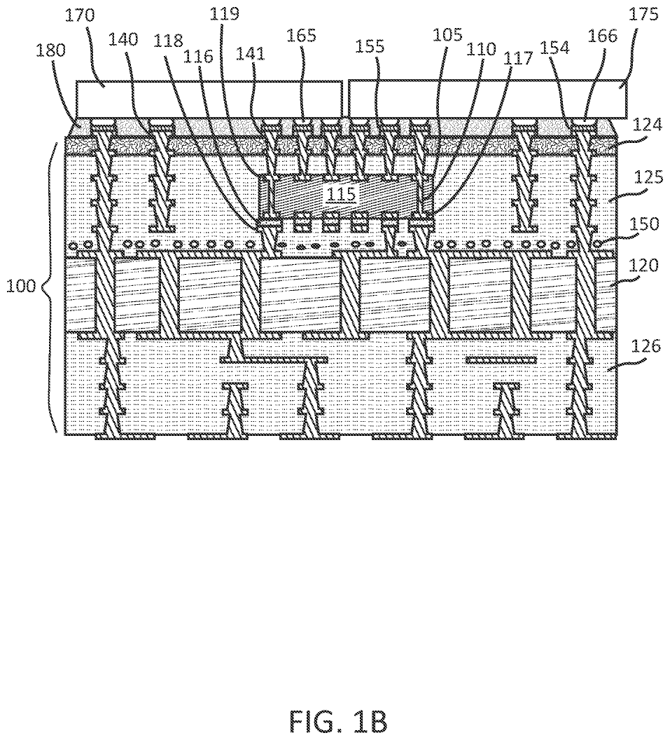

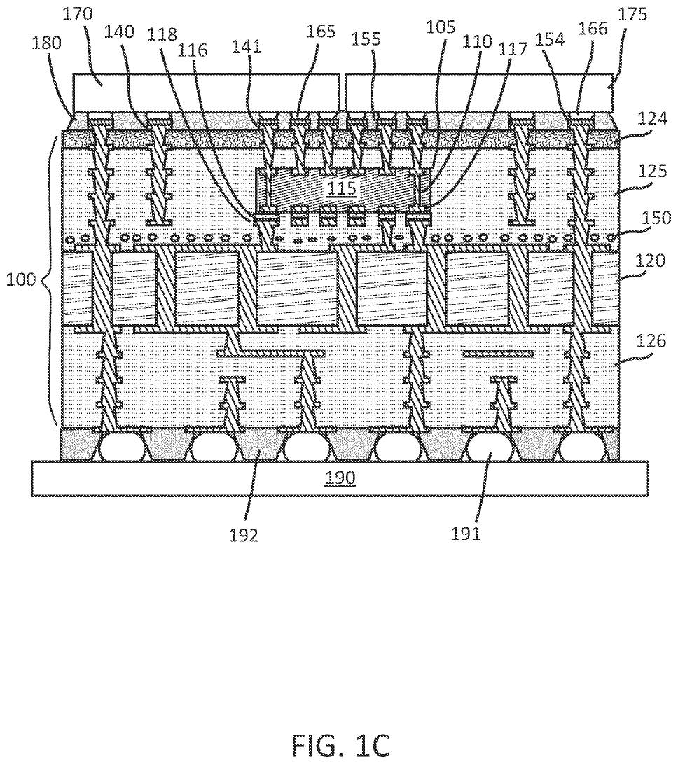

FIGS. 1A-1C illustrate a semiconductor package substrate 100 that includes an interconnect bridge 105. The interconnect bridge 105 is shown as embedded within package substrate 100, however the interconnect bridge 105 can also be partially embedded or not embedded in package substrate 100. The interconnect bridge 105 includes traces and additional vias (that are not depicted for clarity), through-bridge vias 110 (not all are necessarily depicted) and an interconnect bridge substrate 115. The interconnect bridge substrate 115 can include any of the materials described herein for interconnect bridge substrates, such as for example, silicon-containing substrates, glass substrates, polymer substrates, ceramic substrates. Other types of substrate materials are also possible for the interconnect bridge substrate 115. Through-bridge vias 110 and traces are comprised of a conducting material, which can be a metal, such as, for example, copper.

The interconnect bridge 105 is operably electrically connected to the package substrate 100 in an interconnect region through bonding regions 116. Bonding regions 116 can be, for example, solder regions or can be metal on metal regions formed through thermocompression bonding where solder is not present. Bonding regions 116 connect join-side interconnect bridge pads 117 with interconnect-bridge connection package substrate pads 118. Join-side interconnect bridge pads 117 can be comprised of a conducting material, such as, for example, copper. Interconnect-bridge connection package substrate pads 118 can be comprised of a metal such as, for example, copper and can optionally comprise one or more surface layers (not shown) comprising a metal or metal alloy, such as, for example, tin and copper, gold, gold and palladium, nickel, and/or platinum. The description interconnect region refers to the connection of the interconnect bridge 110 with the package substrate 100 so that power and/or signals can be delivered to the interconnect bridge 105 from the board-side of the package substrate 100. (FIG. 1C provides an illustration of a package substrate assembly that includes a board 190.) The interconnect bridge 110 also includes chip-side interconnect bridge pads 119 which can comprise a conducting material, such as, for example, copper. In this example, the bonding regions 116 are partially surrounded by a portion of dielectric layer region 125 and it can be the case that no underfill material is in the interconnect region between the interconnect bridge 105 and the package substrate 100 (i.e., around bonding regions 116). An underfill material can be a flowable material such as, for example, an epoxy, a polyimide, or a thermoplastic material. An underfill material is a flowable material, with or without filler particles, that exhibits, for example, good adhesion, thermal stability, and low moisture absorption. The portion of dielectric layer region 125 around bonding regions 116 can provide an insulative barrier between bonding regions 116 that can enhance signal and power delivery integrity by reducing cross talk. Other numbers of and configurations of are also possible for bonding regions 116, package-side interconnect bridge pads 117, and embedded-bridge connection package substrate pads 118.

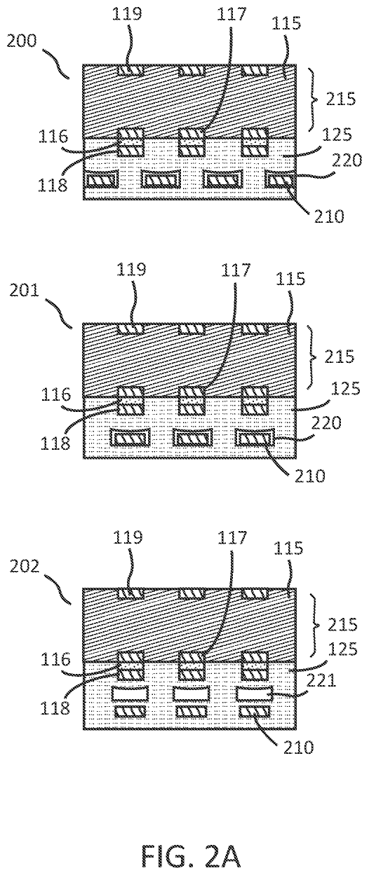

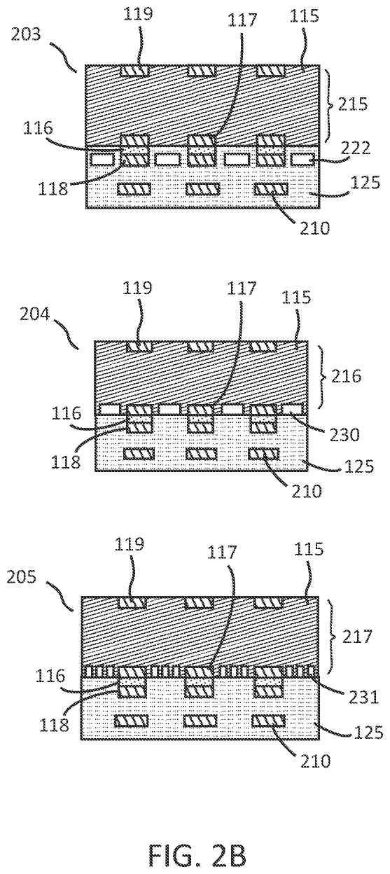

In FIGS. 1A-1C, the package substrate 100 also includes a region of collapsible cavities 150 and 151. Although some collapsible cavities 151 are illustrated as compressed collapsible cavities 151, the actual amount of compression of the collapsible cavities 150 and 151 can be more or less than what is illustrated. Collapsible cavities 150 and 151 can be, for example, gas-filled structures that are collapsible. The collapsible cavities 150 and 151 can be in one or more dielectric layers of package substrate 100. The collapsible cavities 150 and 151 can be, for example, gas-filled glass beads, gas-filled glass fibers, gas bubbles, gas-filled cavities, or SiN or SiOx materials than encase a cavity region filled with a gas. The gas can be, for example, an inert gas, such as for example N₂, or He, or the gas can be air, or a gas comprising N₂ and O₂. Other gases are possible. The collapsible cavities can be fillers in a dielectric layer. The collapsible cavities 150 can also be gas-filled cavities formed through lithographic patterning after laminating a dielectric material. The dielectric layer can be a build-up film or a polyimide dielectric material. The gas-filled glass beads, gas-filled fibers, gas bubbles, gas-filled cavities, or SiN or SiOx materials that encase a cavity region, can have a diameter of, for example, between 3 μm and 30 μm or between 3 μm and 50 μm. FIGS. 2A-2B provide additional examples of alternative collapsible regions that can be in a package substrate. The collapsible regions can be located, for example, in region 160 that is outlined with a dashed line in FIG. 1A.

The package substrate 100 also includes a package substrate core 120 which can be an organic substrate core or glass substrate core as described herein. Although this package substrate 100 includes a substrate core 120, coreless substrates are also possible. Additionally, the package substrate 110 has dielectric layer regions 124, 125 and 126 which can be one or more layers of dielectric (such as build-up layers) having traces and vias 130 and board-side conductive pads 135. Board-side conductive pads 135 can be connected to a board (e.g., a motherboard, a printed circuit board, a system board, a main board, or a logic board). Chip-side conductive pads 140 and 141 can connect to semiconductor chips and are on an opposite side of the package substrate from the board-side conductive pads 135. Chip-side conductive pads 140 and 141 can include an optional surface layer 154 and 155. The surface layer 154 and 155 can be comprised of one or more layers of a metal or metal alloy, comprising, for example, tin, tin and copper, gold, an alloy of gold and palladium, nickel, and/or platinum. Other arrangements and numbers of chip-side conductive pads 140 and 141, board-side conductive pads 135, dielectric layer regions 124, 125 and 126, and traces and vias 130 are also possible. Traces and vias 130 and board-side conductive pads 135 are comprised of a conducting material which can be a metal, such as, for example, copper.

FIGS. 1B-1C provide an assembly that includes package substrate 100 and semiconductor devices 170 and 175 that have been electrically connected to package substrate 100. The semiconductor devices 170 and 175 are electrically connected to package substrate 100 through first level interconnect regions 165 and 166, that can be, for example, comprised of solder, or can be metal-on-metal interconnections, formed, for example through thermocompression bonding without solder. The first level interconnect regions 165 and 166 join the chip-side conductive pads 140 and 141 of the package substrate 100 with first level interconnect pads (not shown) of the semiconductor devices 170 and 175. The chip-side conductive pads 140 and 141 can include an optional surface layer 154 and 155. A dielectric underfill material 180 is between semiconductor devices 170 and 175, which can be, for example, an epoxy, or thermoplastic material. An underfill material can be a flowable material such as, for example, an epoxy, a polyimide, or a thermoplastic material. An underfill material is a flowable material, with or without filler particles, that exhibits, for example, good adhesion, thermal stability, and low moisture absorption. In FIG. 1C the assembly also includes a board 190 which can be, for example, a motherboard, a printed circuit board, a system board, a main board, or a logic board. The package substrate 100 is electrically connected to the board 190 through solder regions 191. Dielectric region 192 has cavities that partially surround solder regions 191. The package substrate 100 can also be electrically connected to board 190 through pins or pads (not shown), for example.

FIGS. 2A-2B show sections of a package substrate in which the section can be located in the region 160 outlined by the dashed line in FIG. 1A. The package substrate sections 200, 201, 202, and 203 include a section of an interconnect bridge 215. The package substrate sections 204 and 205 include a section of an interconnect bridge 216 and 217, respectively. The interconnect bridge sections 215, 216, and 217 include first join-side interconnect bridge conductive pads 117 and chip-side interconnect bridge conductive pads 119 that are on opposite sides of the interconnect bridges (215, 216, and 217). The interconnect bridge sections 215, 216, and 217 also include interconnect bridge substrate 115. For elements where the numbering is the same in FIGS. 2A-2B as in FIGS. 1A-1C, the description for these elements provided herein for FIGS. 1A-1C can also be used for these same-numbered elements in FIGS. 2A-2B. Interconnect bridge substrate 115 can be an interconnect bridge substrate as described herein. Package substrate sections 200, 201, 202, 203, 204, and 205 can also be included in assemblies, such as those illustrated in FIGS. 1B and 1C. The assemblies can include compressible regions as described by package substrate sections 200, 201, 202, 203, 204, and 205 instead of collapsible cavities 150 and 151, or an assembly can include both. Package substrate sections 200, 201, 202, 203, 204, and 205 also include bonding regions 116 and embedded-bridge connection package substrate conductive pads 118.

Package substrate sections 200 and 201 include traces 210 that are partially surrounded by gas-filled cavities 220. In package substrate section 203, the gas-filled cavities are between traces 210 and embedded-bridge connection package substrate conductive pads 118. Gas-filled cavities 220 and 221 are compressible regions (or collapsible regions). Gas-filled cavities 220 and 221 are shown as being compressed (partially collapsed) in FIG. 2A, however, the gas-filled cavities 220 and 221 can be compressed a greater or lesser amount than depicted. Package substrate section 203 of FIG. 2B, also includes gas-filled cavities 222 that are between embedded-bridge connection package substrate conductive pads 118. Gas-filled cavities 222 are compressible (or collapsible) regions. The gas-filled cavities 220, 221, and 222 can have one or more dimensions of, for example, between 3 μm and 30 μm or between 3 μm and 50 μm. The gas-filled cavities 220, 221, and 222 can have other shapes and/or can be more or less deformed than the depictions in FIG. 2A. Package substrate sections 200-203 can have other numbers and arrangements of traces 210 and gas-filled cavities 220, 221 and 222. The gas can be, for example, an inert gas, such as for example N₂, or He, or the gas can be air, or a gas comprising N₂ and O₂. Other gases are possible.

Package substrate sections 204 and 205 include interconnect bridge sections 216 and 217, respectively. Interconnect bridge sections 216 and 217 include cavities 230 and 231, respectively. In package substrate section 204, one cavity 230 is between two package-join side interconnect bridge conductive pads 117, and in package substrate section 205, three cavities 231 are between two package-join side interconnect bridge conductive pads 117, however other numbers of cavities are also possible, such as two cavities 231 or four cavities 231 between package-join side interconnect bridge conductive pads 117. Although not depicted, it is also possible that a portion of dielectric layer region 125 can be in cavities 230 and/or 231. Cavities 230 and 231 can have one or more dimensions that are between 3 μm and 200 μm. Package substrate sections 204 and 205 also include traces 210, however other numbers and arrangements of traces 210 are also possible.

In FIGS. 2A-2B, package substrate sections 200, 201, 202, 203, 204, and 205, the dielectric layer region 125 is partially surrounding bonding regions 116. Additionally, the package substrate sections 200, 201, 202, 203, 204, and 205, can be assembled so that underfill is not used in the interconnect region between the interconnect bridge 215, 216, and 217 and the package substrate 100. Package substrate sections 200, 201, 202, 203, 204, and 205, can be underfill-less, i.e., there is no underfill material, in the join region between the interconnect bridge 215, 216, and 217 and the package substrate 100. An underfill material can be a flowable material such as, for example, an epoxy, a polyimide, or a thermoplastic material. An underfill material is a flowable material, with or without filler particles, that exhibits, for example, good adhesion, thermal stability, and low moisture absorption. Package substrate sections 200, 201, 202, 203, 204, and 205, can be used singularly or in various combinations with or without the collapsible cavities 150 described with respect to FIG. 1A in a semiconductor package substrate 100.

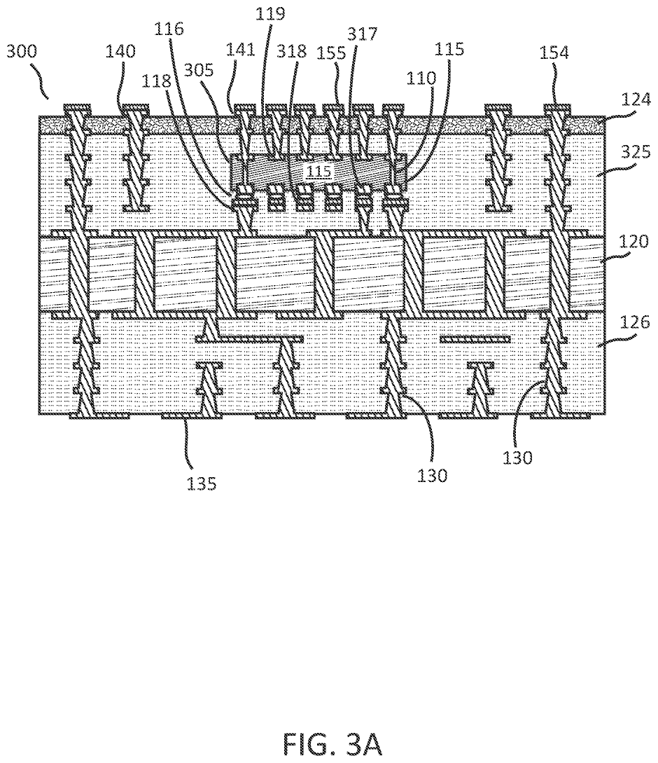

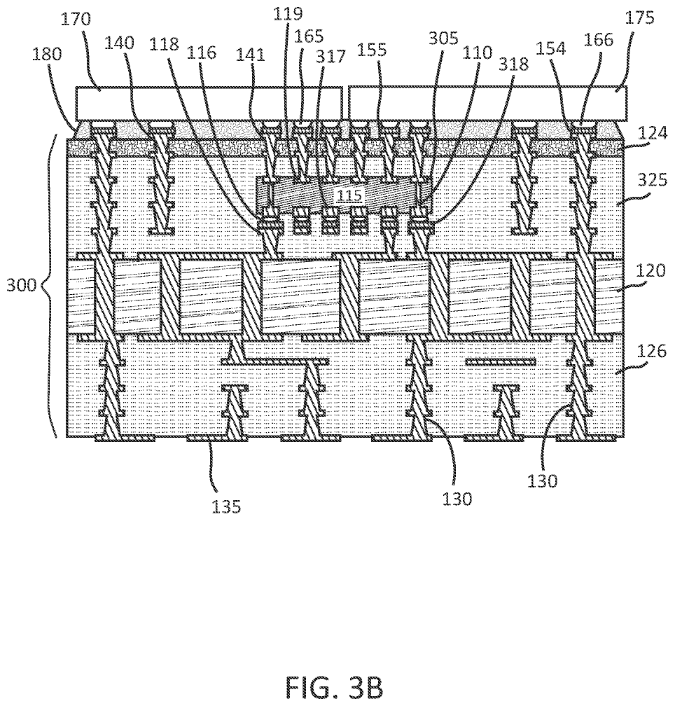

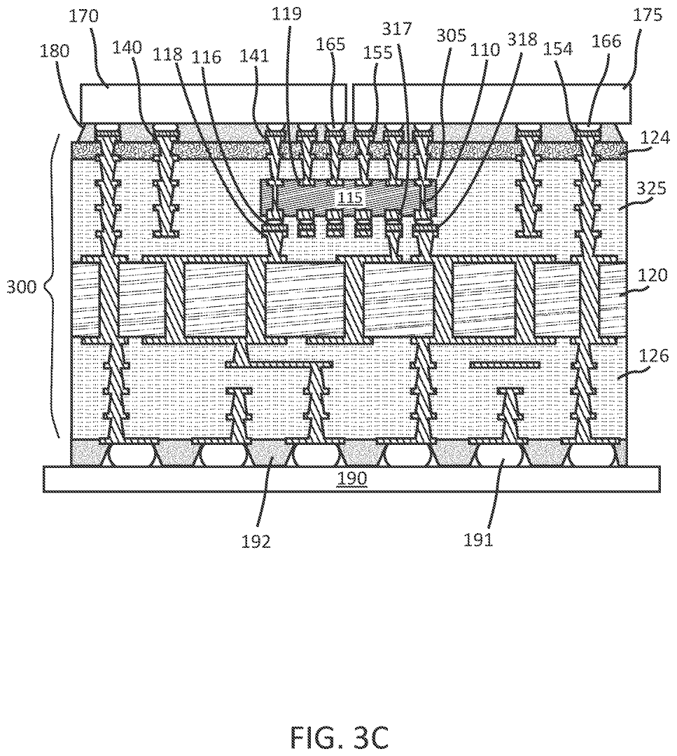

FIGS. 3A-3C illustrate an additional exemplary package substrate 300 and assemblies that include the exemplary package substrate 300. For elements where the numbering is the same in FIGS. 3A-3C as it is in FIGS. 1A-1C, the description provided herein for FIGS. 1A-1C can also be used for these same-numbered elements in FIGS. 3A-3C. The package substrate 300 includes an interconnect bridge 305. The interconnect bridge 305 is shown as embedded within package substrate 300, however the interconnect bridge 305 can also be partially embedded or not embedded in package substrate 300. The interconnect bridge 305 includes traces (not depicted for clarity), through-bridge vias 110 (not all are necessarily depicted) and an interconnect bridge substrate 115. The interconnect bridge 305 also includes join-side interconnect bridge conductive pads 317 that protrude from a surface of the interconnect bridge 305. Join-side interconnect bridge conductive pads 317 are conducting members that can be, for example, pins or rods having, for example, a rectangular or circular footprint. Other shapes are also possible for the protruding join-side interconnect bridge conductive pads 317. Join-side interconnect bridge conductive pads 317 can be comprised of a conducting metal, such as, for example, copper. Join-side interconnect bridge conductive pads 317 protrude into cavities in a build-up layer of the build-up layers of dielectric region 325. The build-up layers can be comprised of, for example, a polyimide or an ABF material. Protruding join-side interconnect bridge conductive pads 317 are electrically connected to the package substrate through bonding regions 116. Bonding regions 116 can be, for example, solder regions or can be metal on metal regions formed through thermocompression bonding where solder is not present. Embedded-bridge connection package substrate conductive pads 118 can include a layer region 318. The package substrate pad layer region 318 can be comprised of one or more layers of a metal or metal alloy, comprising, for example, tin, tin and copper, gold, an alloy of gold and palladium, nickel, and/or platinum. It can be the case that there is no underfill present in the interconnect region between interconnect bridge 305 and package substrate 300 (i.e., around Bonding regions 116). An underfill material can be a flowable material such as, for example, an epoxy, a polyimide, or a thermoplastic material. An underfill material is a flowable material, with or without filler particles, that exhibits, for example, good adhesion, thermal stability, and low moisture absorption.

FIGS. 3B-3C provide an assembly that includes package substrate 300 and semiconductor devices 170 and 175 that have been electrically connected to package substrate 300. The semiconductor devices 170 and 175 are electrically connected to package substrate 100 through first level interconnect regions 165 and 166, that can be, for example, comprised of solder, or can be metal-on-metal interconnections, formed, for example through thermocompression bonding without solder. In FIG. 3C, the assembly also includes a board 190 which can be, for example, a motherboard, a printed circuit board, a system board, a main board, or a logic board. The package substrate 100 is electrically connected to the board 190 through solder regions 191. Dielectric region 192 has cavities that partially surround solder regions 191.

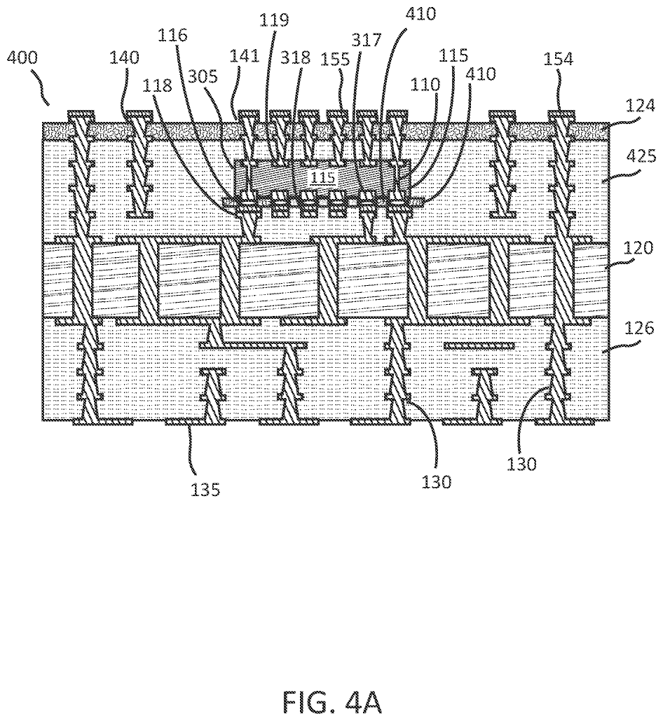

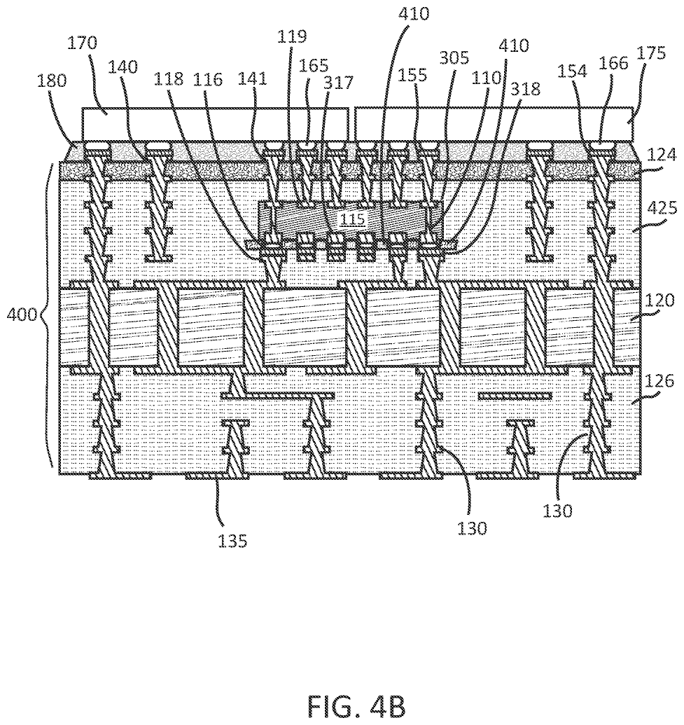

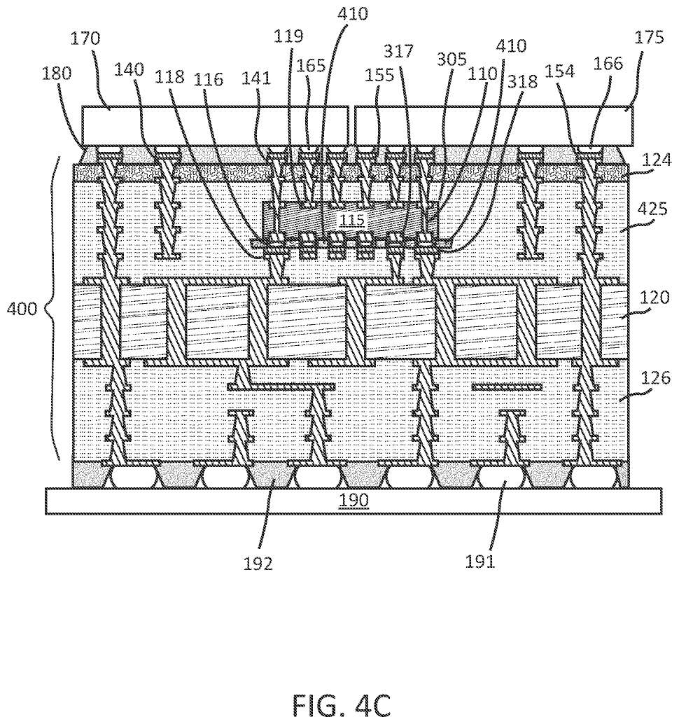

FIGS. 4A-4C provide an additional example of a package substrate 400 that includes an interconnect bridge 305. Where the numbering of parts is the same for FIGS. 4A-4C and FIGS. 1A-1C and 3A-3C, the descriptions herein with respect to FIGS. 1A-1C and 3A-3C are applicable to FIGS. 4A-4C for the same-numbered parts. The interconnect bridge 305 is shown as embedded within package substrate 400, however the interconnect bridge 305 can also be partially embedded or not embedded in package substrate 400. FIG. 4A illustrates a package substrate 400, FIG. 4B illustrates an assembly comprising the package substrate 400 and semiconductor devices 170 and 175, and FIG. 4C illustrates an assembly comprising the package substrate 400, semiconductor devices 170 and 175, and a board 190.

In FIGS. 4A-4C, the interconnect bridge 305 includes join-side interconnect bridge conductive pads 317 that protrude from a surface of the interconnect bridge 305. Protruding join-side interconnect bridge conductive pads 317 are electrically connected to the package substrate through bonding regions 116. Bonding regions 116 can be, for example, solder regions or can be metal on metal regions formed through thermocompression bonding where solder is not present. Embedded-bridge connection package substrate conductive pads 118 can include a layer region 318. The package substrate pad layer region 318 can be comprised of one or more layers of a metal or metal alloy, such as, for example, tin, tin and copper, gold, an alloy of gold and palladium, nickel, and/or platinum. Join-side interconnect bridge conductive pads 317 protrude into cavities in a dielectric layer 410 in the dielectric region 425 of packaging substrate 400. The dielectric layer 410 can be a photo-imageable dielectric, such as for example, polyimide. Dielectric region 425 can be comprised of layers of dielectric material, such as build-up layers. The build-up layers can be comprised of, for example, a polyimide or an ABF material. It can be the case that there is no underfill present between interconnect bridge 305 and package substrate 400. An underfill material can be a flowable material such as, for example, an epoxy, a polyimide, or a thermoplastic material. An underfill material is a flowable material, with or without filler particles, that exhibits, for example, good adhesion, thermal stability, and low moisture absorption.

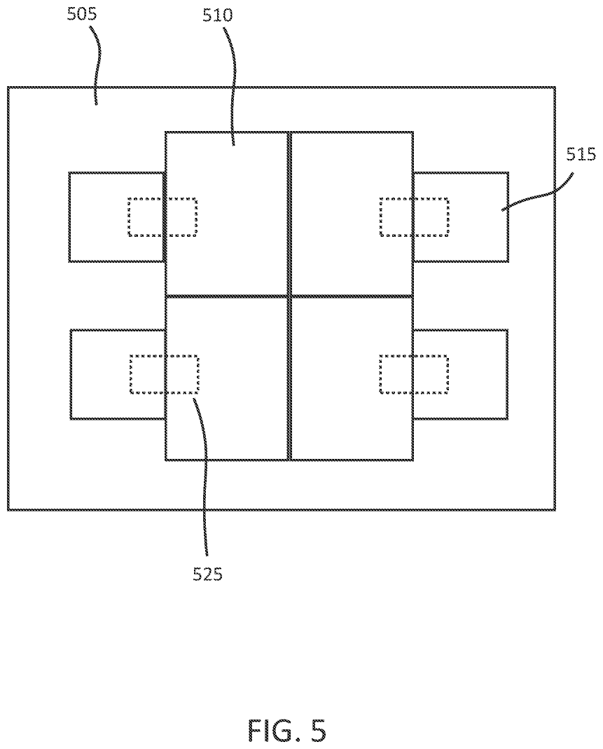

FIG. 5 shows an example configuration for packaged semiconductor devices mounted on a board. Other configurations are possible. In FIG. 5, a board 505 (e.g., a motherboard, a PCB, a system board, a logic board, a circuit board, or a main board) has packaged semiconductor devices 510 and 515 electrically coupled to the board 505. Interconnect bridges 525 are shown with a dashed line and are covered by packaged semiconductor chips 510 and 515 in this view. The interconnect bridges 525 can be more than one interconnect bridge, and can be interconnect bridges that are with or without TBVs, and semiconductor chip package substrates can contain more than one type of interconnect bridge. The interconnect bridges 525 can be housed in or on package substrates as described by FIGS. 1A, 2A-2B, 3A, and/or 4A and the accompanying description herein. One or more semiconductor devices 510 can be, for example, a processor such as, a central processing unit (CPU), a graphics processing unit (GPU) and/or a field programmable gate array (FPGA), and one or more of the chips 515 can be a high bandwidth memory (HBM) die stack and/or one or more of the chips 515 can transceiver die. HBM can be stacked synchronous dynamic random-access memory SDRAM chips. Other semiconductor devices are also possible.

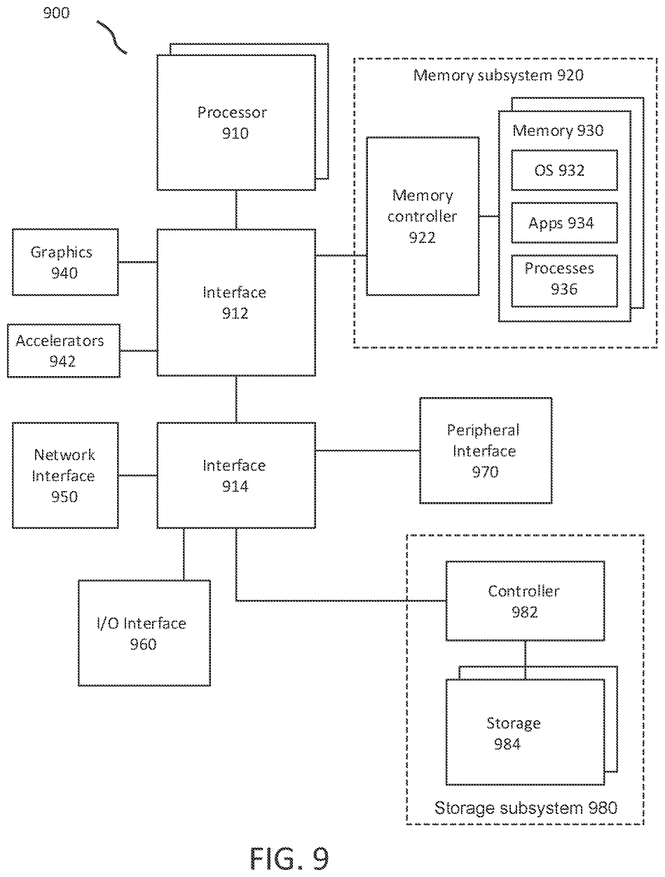

Additionally, in FIGS. 1B, 1C, 3B, 3C, 4B, 4C, and 5 the semiconductor devices 170 and 175 can be any combination of microprocessors, CPUs (central processing units), GPUs (graphics processing units), processing cores, system on a chips, other processing hardware, a combination of processors or processing cores, programmable general-purpose or special-purpose microprocessors, accelerators, DSPs, I/O management, programmable controllers, ASICs, programmable logic devices (PLDs), HBM, and/or other memory devices. These semiconductor chip packages can be heterogeneous packages that incorporate different types of chips into one package. The semiconductor chips can be any of the chips, for example, described herein with respect to FIG. 9. The semiconductor chip packages described herein generally can be part of various larger package structures and configurations and the foregoing examples are not meant to limit the types of assemblies that are possible.

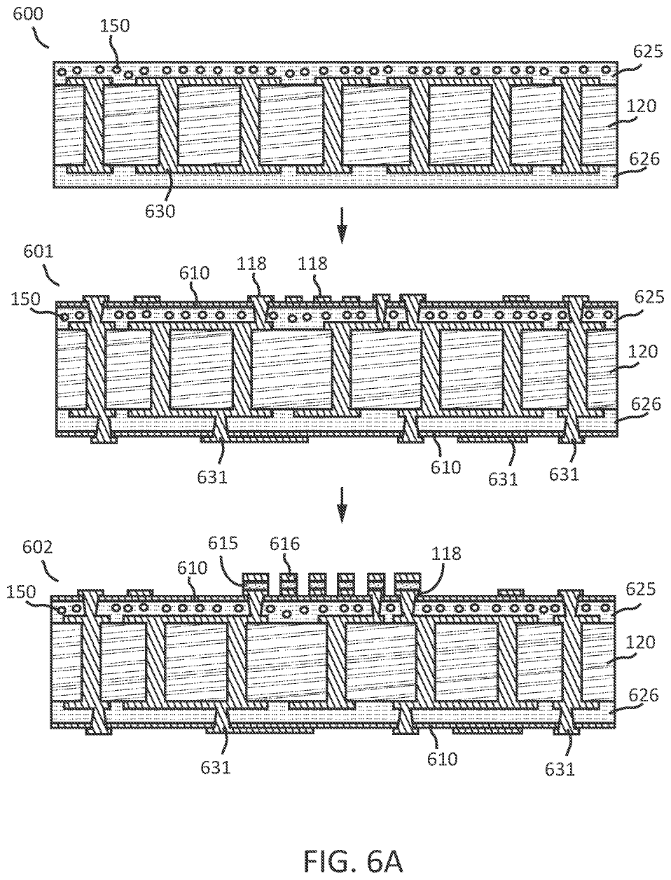

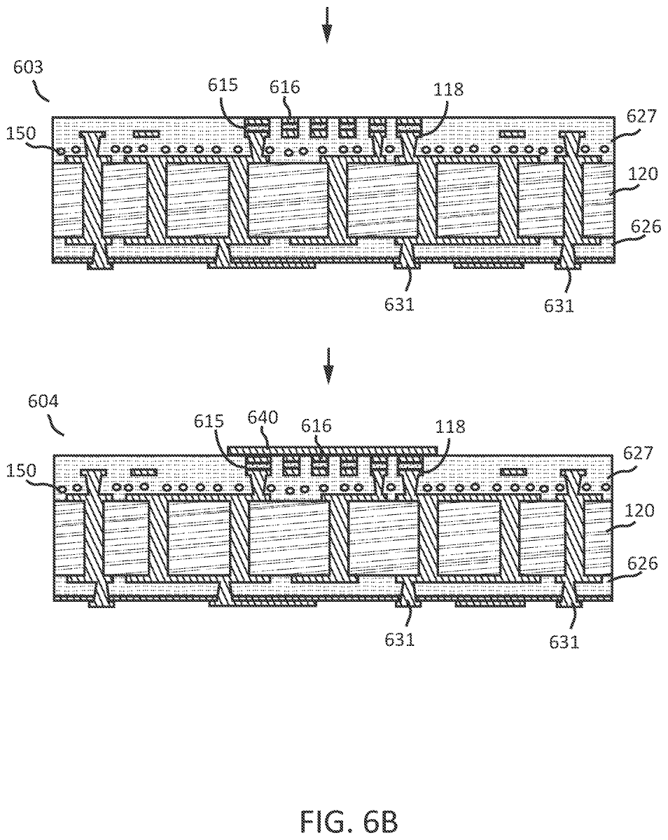

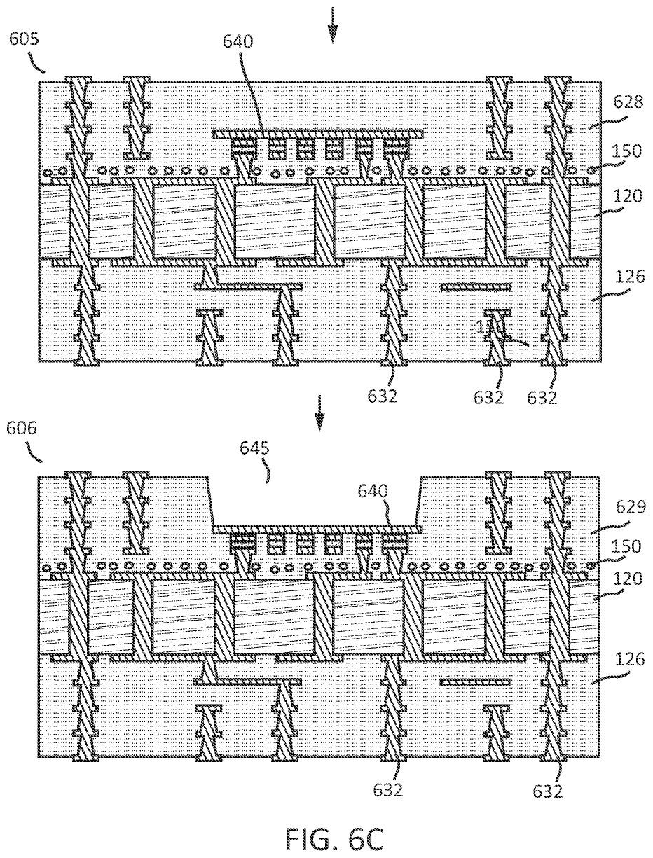

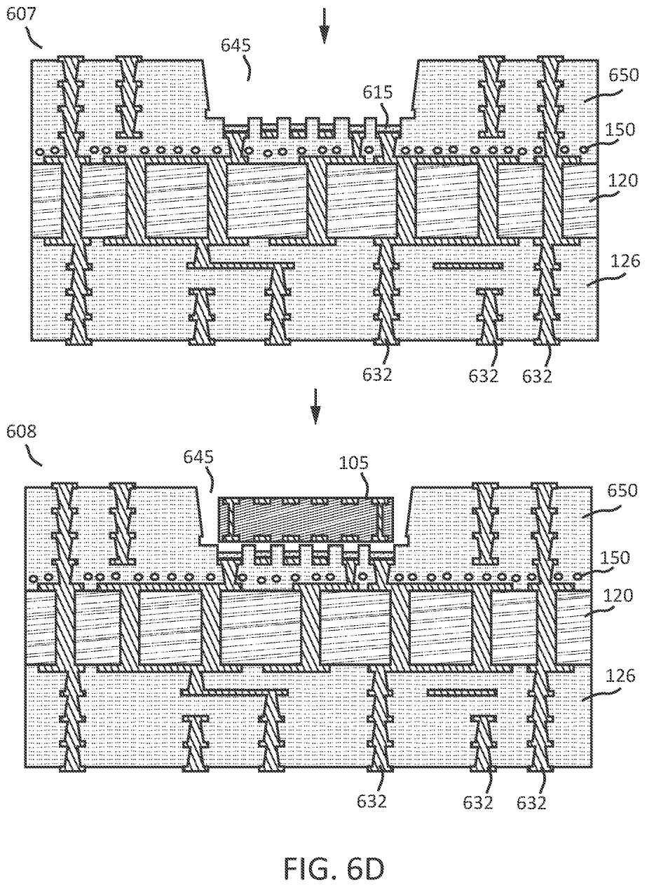

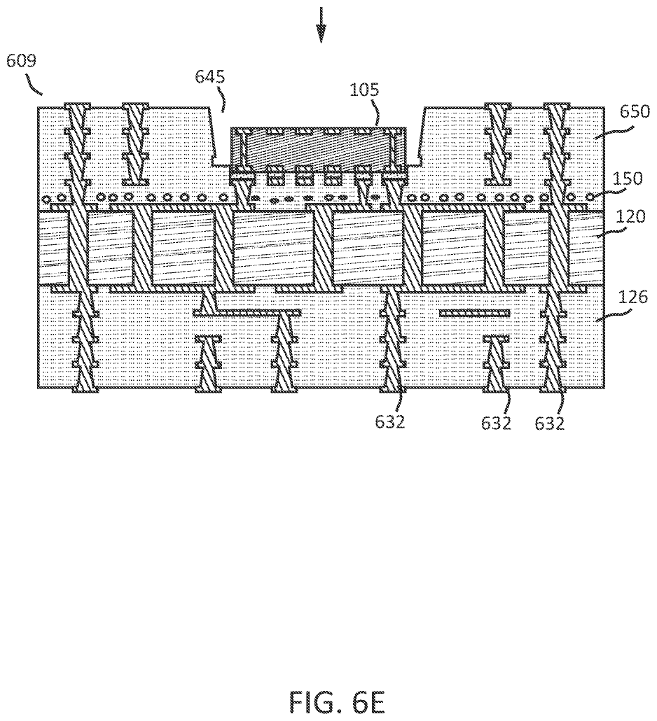

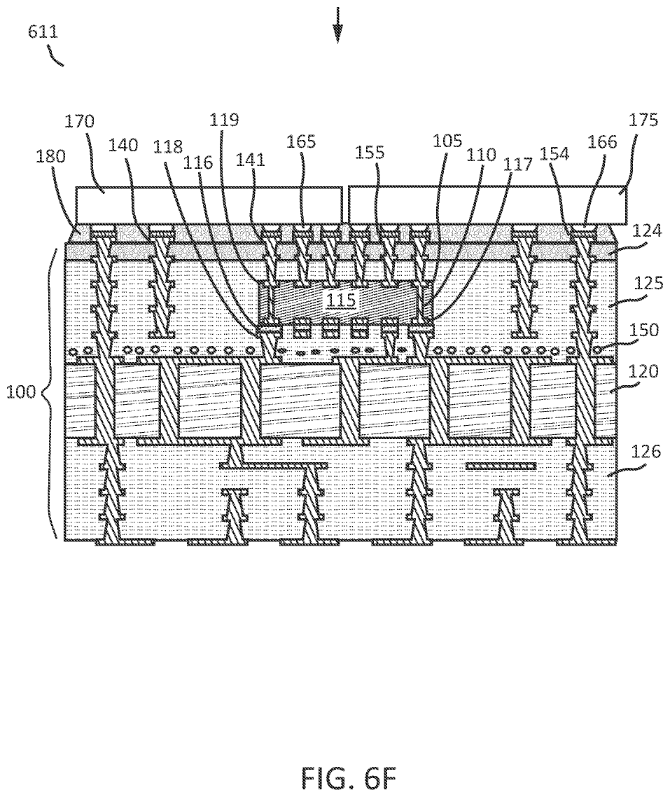

FIGS. 6A-6F provide a method for manufacturing a semiconductor package substrate comprising an interconnect bridge. Where the numbering of parts is the same for FIGS. 6A-6F and FIGS. 1A-1C, the descriptions herein with respect to FIGS. 1A-1C are applicable to FIGS. 6A-6F for the same-numbered parts. In FIG. 6A, a partially manufactured semiconductor substrate 600 comprises a core 120, dielectric layers 625 and 626, and traces and vias 631. Dielectric layers 625 and 626 can be one or more layers of dielectric material, such as ABF. Dielectric layers 625 comprise one or more dielectric layers having collapsible cavities 150 as a filler in the dielectric material. The collapsible cavities 150 can also be gas-filled cavities formed through lithographic patterning after laminating a dielectric material. The collapsible cavities 150 can be, for example, gas-filled glass beads, gas-filled glass fibers, gas bubbles, gas-filled cavities, or SiN or SiOx materials than encase a cavity region filled with a gas. The gas can be, for example, an inert gas, such as for example N₂, or He, or the gas can be air, or a gas comprising N₂ and O₂. Other gases are possible. Traces and vias 630 comprise a conductive material, such as, for example, copper. Partially manufactured package substrate 601 can be produced by lithographically patterning the frontside and backside surfaces of partially manufactured semiconductor substrate 600 and electrolytically depositing copper to create traces and vias. These processes create traces and vias 630, interconnect-bridge connection package substrate conductive pads 118, and sacrificial copper layers 610. To manufacture partially manufactured semiconductor substrate 602, a dual lithographic process can be used to pattern and electrolytically deposit tin (layer 615) and then copper (layer 616) on the interconnect-bridge connection package substrate conductive pads 118.

In FIG. 6B, partially manufactured semiconductor substrate 603 can be produced by a seed etch, a dielectric lamination, and a planarization/reveal process. The dielectric lamination process creates dielectric region 627. Partially manufactured semiconductor substrate 604 can be created by lithographically patterning and electrolytically depositing an etch stop layer 640. An etch stop layer 640 comprising copper is optional and can be used for process flows, such as a cavity formation process. Additional buildup layers and vias and traces can be fabricated creating structure 605 in FIG. 6C, having traces and vias 632 and dielectric region 628. An excimer laser can be used to create a cavity 645 in partially manufactured semiconductor substrate 605, creating partially manufactured semiconductor substrate 606 and dielectric region 629. The cavity creation process can also employ, for example, a CO₂ or a UV laser. Copper layer 640 can act as an etch stop for the excimer laser cavity formation process.

In FIG. 6D, partially manufactured semiconductor substrate 607 having dielectric layer 650 can be created though an alkaline etch process in which the tin layer 615 acts as an etch stop. An interconnect bridge 105 is aligned and placed in cavity 645, as shown by structure 608. The interconnect bridge 105 is pressed into cavity 645 creating partially manufactured package substrate 609. The interconnect bridge 105 can be pressed with enough force to cause the buildup layer underneath to deform. The collapsible cavities 150 can absorb stresses. Thermocompression bonding electrically joins the interconnect bridge 105 to the package substrate. Solder can also be used. The remaining semiconductor package 100 features can be manufactured and semiconductor devices 170 and 175 can be attached producing structure 611 of FIG. 6F. Manufacturing processes include dielectric layer lamination or build-up and formation of traces and vias. FLI pads are also formed. Semiconductor chips can be attached through solder joins or thermocompression bonding joins 165 and 166. A flip chip process can be used. An underfill material 180 can be flowed into the FLI region between semiconductor devices 170 and 175 and the package substrate 100.

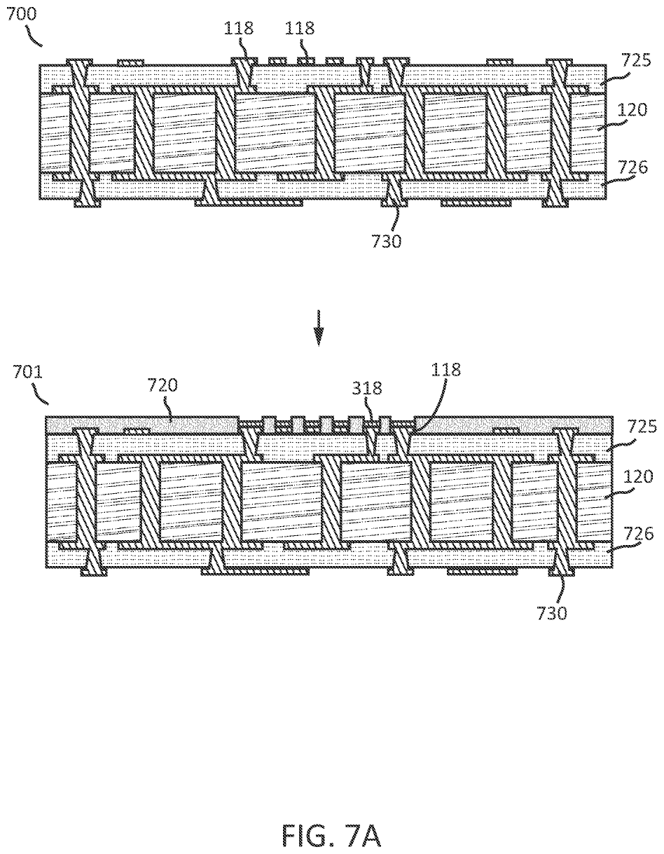

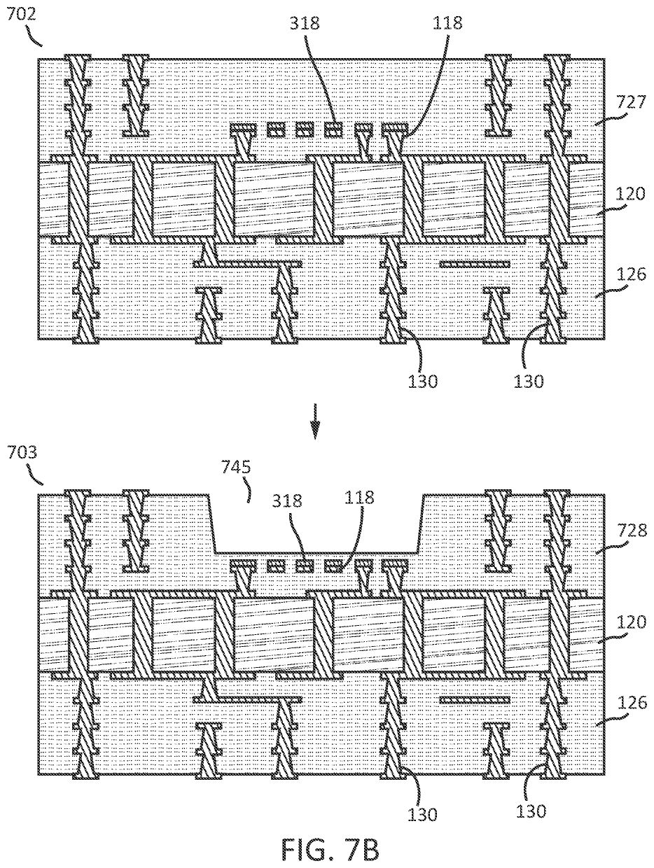

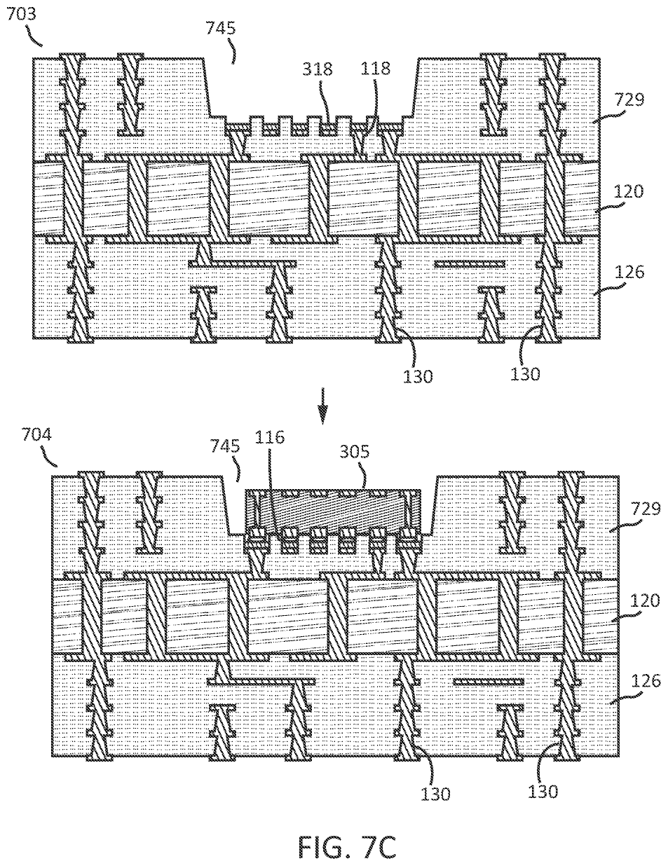

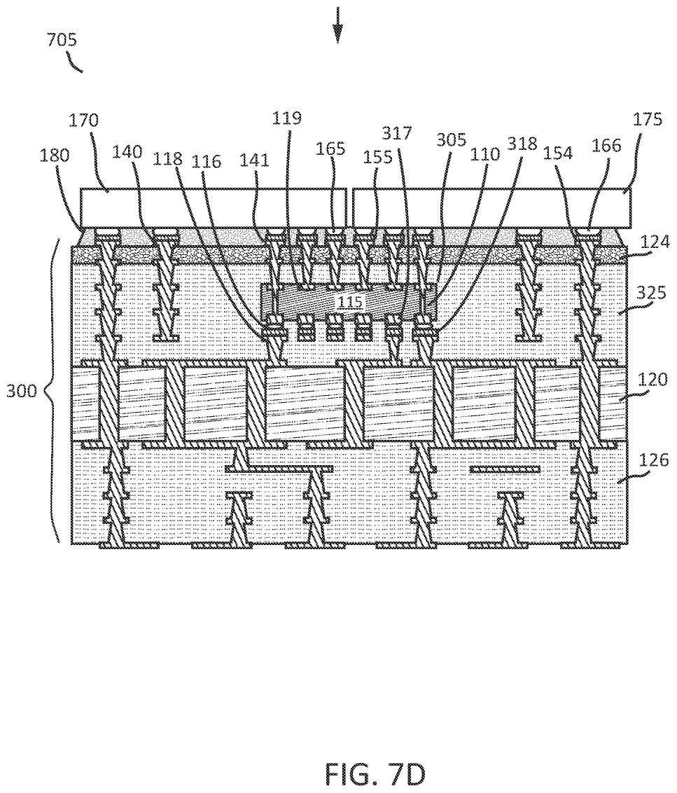

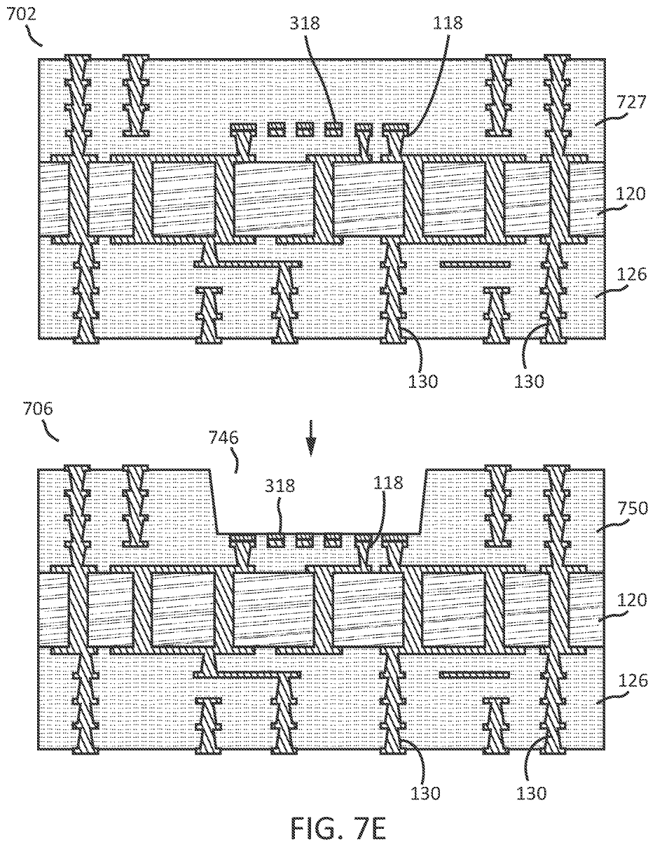

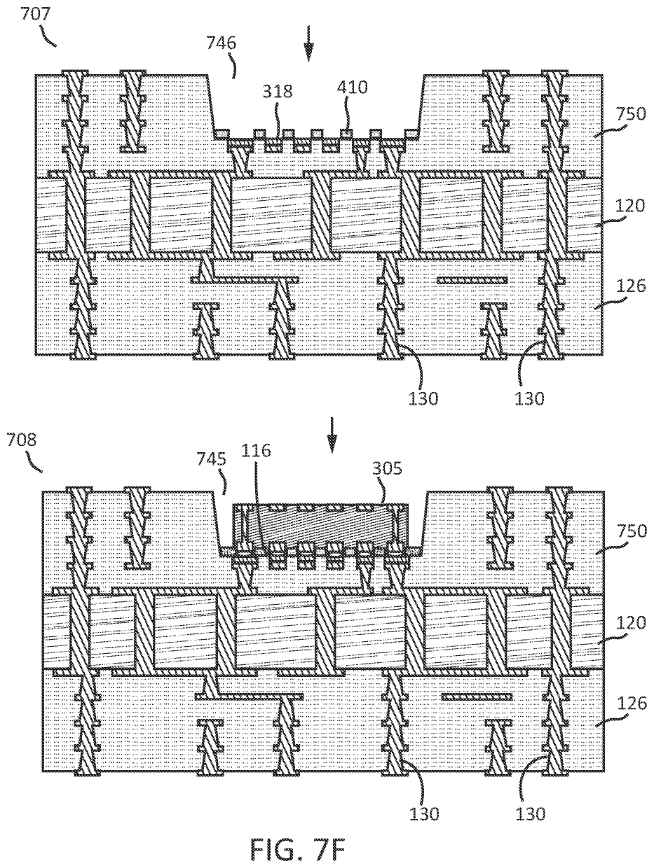

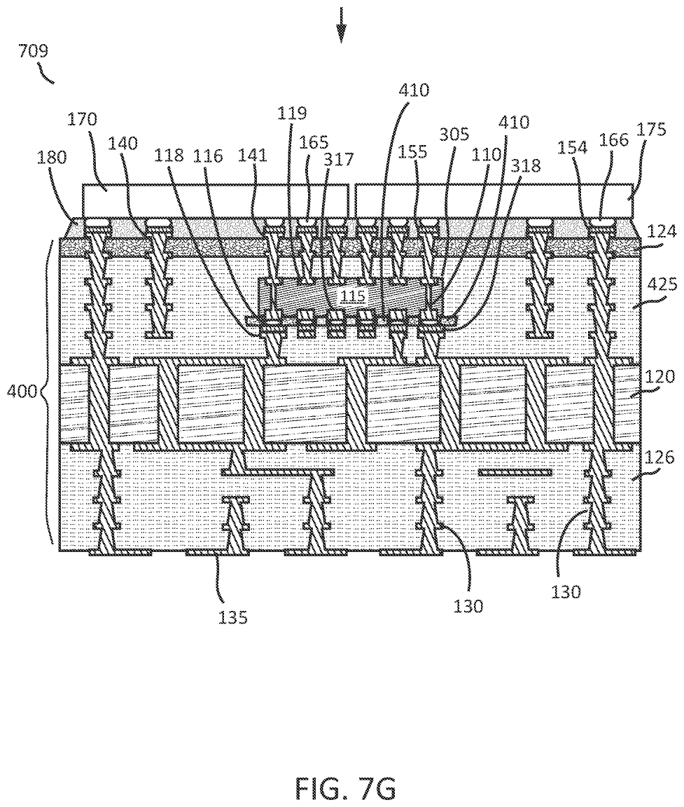

FIGS. 7A-7G illustrate additional methods for manufacturing semiconductor package substrates comprising interconnect bridges. Where the numbering of parts is the same for FIGS. 7A-7G, FIGS. 3A-3C, and FIGS. 4A-4C the descriptions herein with respect to FIGS. 3A-3C and FIGS. 4A-4C are applicable to FIGS. 7A-7G for the same-numbered parts. In FIG. 7A, a partially manufactured semiconductor substrate 700 comprises a core 120, dielectric layers 725 and 726, and traces and vias 730. Dielectric layers 725 and 726 can be one or more layers of dielectric material, such as a build-up film. Partially manufactured semiconductor substrate 700 also comprises the interconnect-bridge connection package substrate conductive pads 118. A lithographic process can be used to deposit and pattern a photoresist layer 720 (such as a dry film photoresist) on partially manufactured semiconductor substrate 700. An electrolytic process can be used to deposit one or more metal or metal alloy surface layers 318 on interconnect-bridge connection package substrate conductive pads 118 creating partially manufactured semiconductor substrate 701. The one or more surface layers 318 can be comprised of, for example, gold, or a gold/palladium alloy. The photoresist layer 720 can be removed, additional buildup layers can be laminated onto partially manufactured semiconductor substrate 701 and additional conductive traces and vias can be formed to produce partially manufactured semiconductor substrate 702 of FIG. 7B, having dielectric region 727. An excimer laser skive process can be used to create cavity 745 in partially manufactured semiconductor substrate 703, creating dielectric region 728. A uniform laser beam profile can be used to create a uniform cavity 745 bottom. A desmear process can be used to clean cavity 745 surfaces. An excimer laser process can be used to reveal surface layer 318 on interconnect-bridge connection package substrate conductive pads 118 as shown in partially manufactured semiconductor substrate 703 of FIG. 7C. Dielectric region 729 is created. A dry desmear process can be used to clean the cavity 745 and surface layer 318 surfaces. An interconnect bridge 305 is aligned, placed in cavity 745, and electrically coupled to package substrate 704 in bonding regions 116 which can be solder regions. The remaining semiconductor package 300 features can be manufactured and semiconductor devices 170 and 175 can be attached producing structure 705 of FIG. 7D. Additional manufacturing processes can include filling the cavity 745 between the dielectric region 729 and the interconnect bridge 305 with a dielectric material, such as, for example, a mold material and/or an epoxy material. Additional manufacturing processes can include dielectric layer lamination or build-up and formation of traces and vias. FLI pads are also formed. A flip chip process can be used to attach semiconductor devices 170 and 175. An underfill material 180 can be flowed into the FLI region between semiconductor devices 170 and 175 and the package substrate 300.

FIGS. 7E-7G provide an alternate process flow starting with partially manufactured semiconductor substrate 702 of FIG. 7B. In FIG. 7E, a laser skive process can be used to create cavity 746 of partially manufactured semiconductor substrate 706. The cavity creation process can employ, for example, a CO₂, an UV (ultraviolet), or an excimer laser. The process creates dielectric region 750 A photo-imageable dielectric can be spray-coated and patterned creating dielectric layer 410 on partially manufactured packaging substrate 707 of FIG. 7F. An interconnect bridge 305 is aligned, placed in cavity 746, and electrically coupled to package substrate 708 in bonding regions 116 which can be solder regions. The remaining semiconductor package 400 features can be manufactured and semiconductor devices 170 and 175 can be attached producing structure 709 of FIG. 7G. Manufacturing processes can include filling the cavity 746 between the dielectric region 750 and the interconnect bridge 305 with a dielectric material, such as, for example, a mold material and/or an epoxy material. Additional manufacturing processes can include dielectric layer lamination or build-up and formation of traces and vias. FLI pads are also formed. Semiconductor chips can be attached through solder joins or thermocompression bonding joins 165 and 166. A flip chip process can be used. An underfill material 180 can be flowed into the FLI region between semiconductor devices 170 and 175 and the package substrate 300.

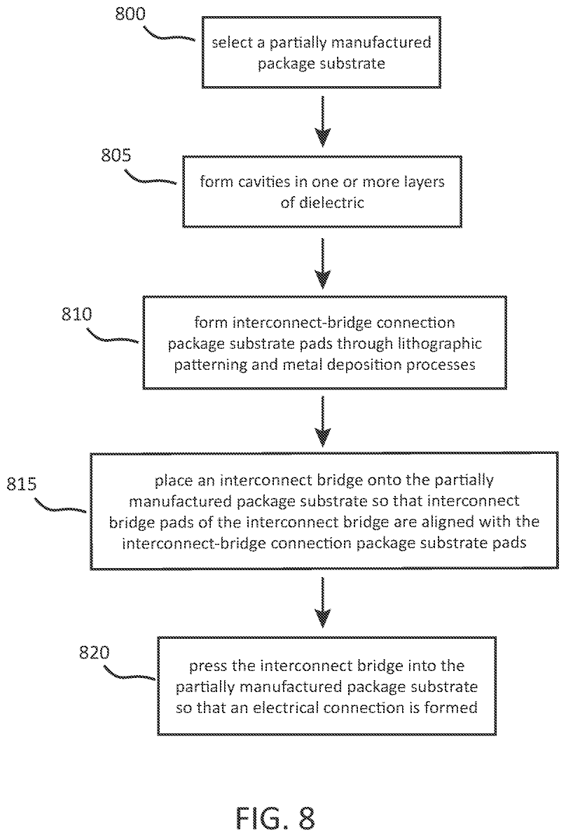

FIG. 8 provides a method for manufacturing a semiconductor package substrate that comprises the gas-filled cavities 220, 221, and 222 of FIGS. 2A-2B. A partially manufactured semiconductor substrate is selected 800. The partially manufactured substrate can have a core or be coreless. One or more cavities are formed in one or more layers of dielectric on the partially manufactured substrate 805. Cavities can be formed around one or more traces, for example, to create a package substrate having gas-filled cavities 220, or cavities can be formed in dielectric material to create a package substrate having one or more gas-filled cavities 221 and/or 222. Gas-filled cavities can be formed, for example, through etching, laser drilling, and techniques that employ sacrificial materials. Interconnect-bridge connection package substrate pads can be formed through lithographic patterning and metal deposition processes 810. An interconnect bridge can be placed onto the partially manufactured substrate so that the interconnect bridge pads of the interconnect bridge are aligned with the interconnect-bridge connection package substrate pads 815. The interconnect bridge can be placed into a cavity formed on the package substrate. The cavity can be formed through, for example, processes described with respect to FIGS. 6B-6C. The interconnect bridge can be pressed into the partially manufactured package substrate so that an electrical connection is formed between the interconnect bridge and the partially manufactured substrate 820. FIGS. 6D-6E illustrate, for example, the alignment of an interconnect bridge and electrical connection formation with the package substrate. Additional manufacturing processes can include forming traces and vias in dielectric layers, forming FLI pads, and attaching semiconductor devices, as described herein and with respect to FIG. 6F, for example.

FIG. 9 depicts an example computing system. The computing system can be a system used, for example, for running equipment in a semiconductor fabrication plant. For example, instructions for operating processing equipment to perform one or more aspects of the process described in FIGS. 6A-6F and FIGS. 7A-7G can be stored and/or run on the computing system. A computing system 900 can include more, different, or fewer features than the ones described with respect to FIG. 9.

Computing system 900 includes processor 910, which provides processing, operation management, and execution of instructions for system 900. Processor 910 can include any type of microprocessor, CPU (central processing unit), GPU (graphics processing unit), processing core, or other processing hardware to provide processing for system 900, or a combination of processors or processing cores. Processor 910 controls the overall operation of system 900, and can be or include, one or more programmable general-purpose or special-purpose microprocessors, DSPs, programmable controllers, ASICs, programmable logic devices (PLDs), or the like, or a combination of such devices.

In one example, system 900 includes interface 912 coupled to processor 910, which can represent a higher speed interface or a high throughput interface for system components needing higher bandwidth connections, such as memory subsystem 920 or graphics interface components 940, and/or accelerators 942. Interface 912 represents an interface circuit, which can be a standalone component or integrated onto a processor die. Where present, graphics interface 940 interfaces to graphics components for providing a visual display to a user of system 900. In one example, the display can include a touchscreen display.

Accelerators 942 can be a fixed function or programmable offload engine that can be accessed or used by a processor 910. For example, an accelerator among accelerators 942 can provide data compression (DC) capability, cryptography services such as public key encryption (PKE), cipher, hash/authentication capabilities, decryption, or other capabilities or services. In some cases, accelerators 942 can be integrated into a CPU socket (e.g., a connector to a motherboard (or circuit board, printed circuit board, mainboard, system board, or logic board) that includes a CPU and provides an electrical interface with the CPU). For example, accelerators 942 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 942 can provide multiple neural networks, CPUs, processor cores, general purpose graphics processing units, or graphics processing units can be made available for use by artificial intelligence (AI) or machine learning (ML) models.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 930 stores and hosts, among other things, operating system (OS) 932 that provides a software platform for execution of instructions in system 900, and stores and hosts applications 934 and processes 936. In one example, memory subsystem 920 includes memory controller 922, which is a memory controller to generate and issue commands to memory 930. The memory controller 922 can be a physical part of processor 910 or a physical part of interface 912. For example, memory controller 922 can be an integrated memory controller, integrated onto a circuit within processor 910.

System 900 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interface (PCI) or PCI express (PCIe) bus, a Hyper Transport or industry standard architecture (ISA) bus, a small computer system interface (SCSI) bus, a universal serial bus (USB), or a Firewire bus.

In one example, system 900 includes interface 914, which can be coupled to interface 912. In one example, interface 914 represents an interface circuit, which can include standalone components and integrated circuitry. In one example, user interface components or peripheral components, or both, couple to interface 914. Network interface 950 provides system 900 the ability to communicate with remote devices (e.g., servers or other computing devices) over one or more networks. Network interface 950 can include an Ethernet adapter, wireless interconnection components, cellular network interconnection components, USB, or other wired or wireless standards-based or proprietary interfaces. Network interface 950 can transmit data to a device that is in the same data center or rack or a remote device, which can include sending data stored in memory.

Some examples of network interface 950 are part of an infrastructure processing unit (IPU) or data processing unit (DPU), or are used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that can have been performed by a CPU. The IPU or DPU can include one or more memory devices.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include additional types of hardware interfaces, such as, for example, interfaces to semiconductor fabrication equipment and/or electrostatic charge management devices.

In one example, system 900 includes storage subsystem 980. Storage subsystem 980 includes storage device(s) 984, which can be or include any conventional medium for storing data in a nonvolatile manner, such as one or more magnetic, solid state, and/or optical based disks. Storage 984 can be generically considered to be a “memory,” although memory 930 is typically the executing or operating memory to provide instructions to processor 910. Whereas storage 984 is nonvolatile, memory 930 can include volatile memory (e.g., the value or state of the data is indeterminate if power is interrupted to system 900). In one example, storage subsystem 980 includes controller 982 to interface with storage 984. In one example controller 982 is a physical part of interface 912 or processor 910 or can include circuits or logic in both processor 910 and interface 914.

A power source (not depicted) provides power to the components of system 900. More specifically, power source typically interfaces to one or multiple power supplies in system 900 to provide power to the components of system 900.

Exemplary systems may be implemented in various types of computing, smart phones, tablets, personal computers, and networking equipment, such as switches, routers, racks, and blade servers such as those employed in a data center and/or server farm environment.

An apparatus can comprise a substrate wherein the substrate can comprise layers of dielectric material, wherein the substrate can comprise conductive traces and vias in the layers of dielectric material, and wherein the substrate can comprise one or more dielectric layers that comprise one or more gas-filled cavities; and an interconnect bridge on the substrate wherein the interconnect bridge can comprise conductive traces and conductive through-bridge vias, and wherein the interconnect bridge is electrically connected to the substrate. The gas-filled cavities can comprise gas-filled glass beads, gas-filled glass fibers, or gas bubbles. In the apparatus, it can be the case that there is no underfill material between the substrate and the interconnect bridge in an interconnect region between the substrate and the interconnect bridge. A gas-filled cavity of the one or more gas-filled cavities can comprise a cavity that partially surrounds a trace in the substrate. The apparatus of claim 1 wherein a gas-filled cavity of the one or more gas-filled cavities has dimensions between 3 μm and 50 μm. The substrate can also comprise a core and the core can be comprised of a solid amorphous glass material.

### Examples

An apparatus can comprise a substrate wherein the substrate can comprise layers of dielectric material, wherein the substrate can comprise conductive traces and vias in the layers of dielectric material, wherein the substrate can comprise first conductive pads, and wherein a layer of the layers of dielectric material can comprise cavities; and an interconnect bridge in the substrate wherein the interconnect bridge comprises conductive traces, conductive vias, and conductive through-bridge vias, wherein the interconnect bridge comprises second conductive pads that protrude from a surface of the interconnect bridge, wherein a second conductive pad protrudes into a cavity of the layer dielectric material that comprises cavities, and wherein a second conductive pad is electrically connected to a first conductive pad. The layer of dielectric material that comprises cavities can be comprised of a polyimide or a build-up film. The layer of dielectric material that comprises cavities can be comprised of a photo-imageable dielectric material. It can be the case that there is no underfill material between the substrate and the interconnect bridge in an interconnect region between the substrate and the interconnect bridge. The first conductive pads can be comprised of copper. The first conductive pads can be comprised of one or more layers of material that comprise tin, gold, palladium, platinum, nickel, or a combination thereof. The second conductive pad can be electrically connected to the first conductive pad through a solder region. The interconnect bridge can be embedded in the substrate. The substrate can comprise a core and the core can be comprised of a solid amorphous glass material.

An apparatus can comprise a substrate wherein the substrate can comprise layers of dielectric material, wherein the substrate can comprise conductive traces and vias in the layers of dielectric material, wherein the substrate can comprise first conductive pads, and wherein a layer of the layers of dielectric material can comprise cavities; and an interconnect bridge in the substrate wherein the interconnect bridge comprises conductive traces, conductive vias, and conductive through-bridge vias, wherein the interconnect bridge comprises second conductive pads that protrude from a surface of the interconnect bridge, wherein a second conductive pad protrudes into a cavity of the layer dielectric material that comprises cavities, and wherein a second conductive pad is electrically connected to a first conductive pad. The layer of dielectric material that comprises cavities can be comprised of a polyimide or a build-up film. The layer of dielectric material that comprises cavities can be comprised of a photo-imageable dielectric material. It can be the case that there is no underfill material between the substrate and the interconnect bridge in an interconnect region between the substrate and the interconnect bridge. The first conductive pads can be comprised of copper. The first conductive pads can be comprised of one or more layers of material that comprise tin, gold, palladium, platinum, nickel, or a combination thereof. The second conductive pad can be electrically connected to the first conductive pad through a solder region. The interconnect bridge can be embedded in the substrate. The substrate can comprise a core and the core can be comprised of a solid amorphous glass material.

A method for manufacturing a package substrate can comprise laminating a partially manufactured package substrate with a dielectric material comprising gas-filled cavities; forming interconnect-bridge connection package substrate pads through lithographic patterning and metal deposition processes on the partially manufactured package substrate; placing an interconnect bridge on the partially manufactured package substrate so that interconnect bridge pads of the interconnect bridge are aligned with the interconnect-bridge connection package substrate pads; and pressing the interconnect bridge into the partially manufactured package substrate so that an electrical connection is formed between the interconnect bridge pads and the interconnect-bridge connection package substrate pads. In the method, the gas-filled cavities can comprise gas-filled glass beads, gas-filled glass fibers, or gas bubbles. It can be the case that, in the method an underfill material is not flowed into an interconnect region between the interconnect bridge and the partially manufactured package substrate. In the method, the interconnect bridge can comprise traces, vias, and through-bridge vias. In the method, the electrical connection can be formed through thermocompression bonding.

An assembly can comprise a processor and a package substrate, wherein the package substrate comprises: a substrate wherein the substrate comprises layers of dielectric material, wherein conductive traces and vias are in the layers of dielectric material, wherein the substrate comprises first conductive pads, and wherein the substrate comprises a layer of dielectric material that comprises cavities; and a interconnect bridge in the substrate wherein the interconnect bridge comprises conductive traces, conductive vias, and conductive through-bridge vias, wherein the interconnect bridge comprises second conductive pads that protrude from a surface of the interconnect bridge, wherein a second conductive pad protrudes into a cavity of the layer dielectric material that comprises cavities, and wherein a second conductive pads is electrically connected to a first conductive pad, and wherein the processor is electrically coupled to the interconnect bridge. The layer of dielectric material that comprises cavities can be comprised of a build-up film. The layer of dielectric material that comprises cavities can be comprised of a photo-imageable dielectric material. The first conductive pads can comprise one or more layers of material that comprise tin, gold, palladium, platinum, nickel, or a combination thereof. The conductive through-bridge vias are capable of supplying power from a circuit board to the processor.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a substrate wherein the substrate comprises layers of dielectric material, wherein the substrate comprises conductive traces and vias in the layers of dielectric material, and wherein the substrate comprises one or more dielectric layers that comprise one or more gas-filled cavities; and
an interconnect bridge on the substrate wherein the interconnect bridge comprises conductive traces and conductive through-bridge vias, and wherein the interconnect bridge is electrically connected to the substrate.

2. The apparatus of claim 1 wherein the one or more gas-filled cavities comprise gas-filled glass beads, gas-filled glass fibers, or gas bubbles.

3. The apparatus of claim 1 wherein there is no underfill material between the substrate and the interconnect bridge in an interconnect region between the substrate and the interconnect bridge.

4. The apparatus of claim 1 wherein a gas-filled cavity of the one or more gas-filled cavities comprises a cavity that partially surrounds a trace in the substrate.

5. The apparatus of claim 1 wherein a gas-filled cavity of the one or more gas-filled cavities has dimensions between 3 μm and 50 μm.

6. The apparatus of claim 1 wherein the substrate also comprises a core and the core is comprised of a solid amorphous glass material.

7. An apparatus comprising:
a substrate wherein the substrate comprises layers of dielectric material, wherein the substrate comprises conductive traces and vias in the layers of dielectric material, wherein the substrate comprises first conductive pads, and wherein a layer of the layers of dielectric material comprises cavities; and
an interconnect bridge in the substrate wherein the interconnect bridge comprises conductive traces, conductive vias, and conductive through-bridge vias, wherein the interconnect bridge comprises second conductive pads that protrude from a surface of the interconnect bridge, wherein a second conductive pad protrudes into a cavity of the layer dielectric material that comprises cavities, and wherein a second conductive pad is electrically connected to a first conductive pad.

8. The apparatus of claim 7 wherein the layer of dielectric material that comprises cavities is comprised of a polyimide or a build-up film.

9. The apparatus of claim 7 wherein the layer of dielectric material that comprises cavities is comprised of a photo-imageable dielectric material.

10. The apparatus of claim 7 wherein there is no underfill material between the substrate and the interconnect bridge in an interconnect region between the substrate and the interconnect bridge.

11. The apparatus of claim 7 wherein the first conductive pads are comprised of copper.

12. The apparatus of claim 7 wherein the first conductive pads comprise one or more layers of material that are comprised of tin, gold, palladium, platinum, nickel, or a combination thereof.

13. The apparatus of claim 7 wherein the second conductive pad is electrically connected to the first conductive pad through a solder region.

14. The apparatus of claim 7 wherein the interconnect bridge is embedded in the substrate.

15. The apparatus of claim 7 wherein the substrate also comprises a core and the core is comprised of a solid amorphous glass material.

16. An assembly comprising:
a processor; and
a package substrate, wherein the package substrate comprises:
a substrate wherein the substrate comprises layers of dielectric material, wherein conductive traces and vias are in the layers of dielectric material, wherein the substrate comprises first conductive pads, and wherein the substrate comprises a layer of dielectric material that comprises cavities; and
an interconnect bridge in the substrate wherein the interconnect bridge comprises conductive traces, conductive vias, and conductive through-bridge vias, wherein the interconnect bridge comprises second conductive pads that protrude from a surface of the interconnect bridge, wherein a second conductive pad protrudes into a cavity of the layer dielectric material that comprises cavities, and wherein a second conductive pads is electrically connected to a first conductive pad,
and wherein the processor is electrically coupled to the interconnect bridge.

17. The assembly of claim 16 wherein the layer of dielectric material that comprises cavities is comprised of a build-up film.

18. The assembly of claim 16 wherein the layer of dielectric material that comprises cavities is comprised of a photo-imageable dielectric material.

19. The assembly of claim 16 wherein the first conductive pads comprise one or more layers of material that are comprised of tin, gold, palladium, platinum, nickel, or a combination thereof.

20. The assembly of claim 16 wherein the conductive through-bridge vias are capable of supplying power from a circuit board to the processor.
